(19) United States
(12) Patent Application Publication
(10) Pub. No.: US 2023/0025153 A1
(43) Pub. Date: Jan. 26, 2023

(54) RANDOM NUMBER GENERATING CIRCUIT FOR GENERATING RANDOM NUMBER BASED ON PLURALITY OF SAMPLING SIGNALS, AND OPERATING METHOD THEREOF

(71) Applicant: SAMSUNG ELECTRONICS CO., LTD., Suwon-si (KR)

(72) Inventors: Yunhyeok CHOI, Hwaseong-si (KR); Yongki LEE, Suwon-si (KR); Sumin NOH, Hwaseong-si (KR); Jieun PARK, Suwon-si (KR); Bohdan KARPINSKYY, Suwon-si (KR)

(73) Assignee: SAMSUNG ELECTRONICS CO., LTD., Suwon-si (KR)

(21) Appl. No.: 17/867,150

(22) Filed: Jul. 18, 2022

(30) Foreign Application Priority Data
Jul. 22, 2021 (KR) 10-2021-0096707

(51) Int. Cl. G06F 7/58

(52) U.S. Cl. CPC G06F 7/582

(57) ABSTRACT

A random number generating circuit includes: an oscillation circuit including a plurality of first delay elements connected to each other in series to generate an oscillation signal; a sampling circuit including a plurality of second delay elements connected to each other in series to generate a plurality of sampling signals by sampling the oscillation signal at a plurality of sampling points in time based on the plurality of second delay elements; and a random number determining circuit configured to generate a random number based on a target sampling point in time associated with a target sampling signal in which a first logic level transition occurs from among the plurality of sampling signals, wherein the plurality of sampling points includes the target sampling point.

### CROSS-REFERENCE TO RELATED APPLICATION

This application is based on and claims priority under 35 U.S.C. §119 to Korean Patent Application No. 10-2021-0096707, filed on Jul. 22, 2021, in the Korean Intellectual Property Office, the disclosure of which is incorporated by reference herein in its entirety.

### BACKGROUND

The present disclosure relates to a random number generating circuit, and more particularly, to a random number generating circuit for generating a random number based on a plurality of sampling signals, and an operating method thereof.

In general, in data communication using a smart card, an encryption key is used to protect user's personal information. A random number is required to generate such an encryption key, and the random number may be generally classified into a pseudo random number and a true random number.

The pseudo random number is artificially generated using a logic circuit and software, and such a pseudo-random number can be obtained using a Rivest-Shamir-Adelman (RSA) method, an elliptic curve cryptosystem, or the like.

The true random number is generated by using a physical phenomenon that exists in the natural world, and examples of such physical phenomena may include thermal noise of resistors, short-circuit noise of semiconductor PN junctions, short-circuit noise caused by photon generation, wave generation of radiation, and metastability. The true random number is also called a physical random number because of its unpredictability.

A ring oscillator may vibrate by repeatedly inverting and amplifying an output signal. A transition time point of a signal output by the ring oscillator may be randomly changed according to a Gaussian distribution, and such a Gaussian distribution range may be referred to as jitter. A random number generator may generate a true random number based on jitter that is randomly changed.

### SUMMARY

One or more example embodiments provide a circuit for generating a random number from an oscillation signal including little jitter, based on a plurality of sampling signals.

In accordance with an aspect of an example embodiment, there is provided a random number generating circuit including: an oscillation circuit including a plurality of first delay elements connected to each other in series to generate an oscillation signal; a sampling circuit including a plurality of second delay elements connected to each other in series to generate a plurality of sampling signals by sampling the oscillation signal at a plurality of sampling points in time based on the plurality of second delay elements; and a random number determining circuit configured to generate a random number based on a target sampling point in time associated with a target sampling signal in which a first logic level transition occurs from among the plurality of sampling signals, wherein the plurality of sampling points includes the target sampling point.

In accordance with an aspect of an example embodiment, there is provided a random number generator including: a first delay element chain including a plurality of first delay elements connected to each other in series to generate an oscillation signal; a second inverter chain including a plurality of second inverters connected to each other in series to generate a plurality of delay signals delayed by different delay times from a clock signal; a sampling chain configured to generate a plurality of sampling signals of the oscillation signal based on the plurality of delay signals; and a random number output circuit configured to determine a sampling signal having a logic level that is different from a logic level of a previous sampling signal, from among the plurality of sampling signals, as a target sampling signal, and generate a random number based on a sampling order of the target sampling signal from among the plurality of sampling signals.

In accordance with an aspect of an example embodiment, there is provided a method of operating a random number generating circuit for generating a random number based on a plurality of sampling signals, the method including: generating an oscillation signal by a ring oscillator; generating a plurality of sampling signals by sampling the oscillation signal at different sampling points in time; determining a sampling point associated with a target sampling signal in which a first logic level transition occurs, from among the plurality of sampling signals; and generating a random number based on the sampling point of the target sampling signal..

### BRIEF DESCRIPTION OF THE DRAWINGS

Embodiments of the disclosure will be more clearly understood from the following detailed description taken in conjunction with the accompanying drawings in which:

FIG. 1 is a block diagram of a configuration of a random number generating circuit according to an embodiment;

FIG. 2 is a circuit diagram of an oscillating circuit according to an embodiment;

FIG. 3 is a timing diagram of jitter included in an oscillation signal according to an embodiment;

FIGS. 4A and 4B are circuit diagrams of a sampling circuit according to an embodiment;

FIG. 5 is a timing diagram of sampling signals generated corresponding to respective sampling points when an oscillation signal is advanced compared to an ideal oscillation signal, according to an embodiment;

FIG. 6 is a timing diagram of sampling signals generated corresponding to respective sampling points when an oscillation signal is delayed compared to an ideal oscillation signal, according to an embodiment;

FIG. 7 is a circuit diagram of a sampling circuit according to another embodiment;

FIG. 8 is a timing diagram illustrating an example in which sampling signals are generated corresponding to each sampling point based on an oscillation signal generated according to the embodiment of FIG. 7;

FIGS. 9, 10, 11 and 12 are circuit diagrams of random number determining circuits according to different embodiments;

FIG. 13 is a circuit diagram of a random number determining circuit that generates a random number when the random number determining circuit receives different numbers of sampling signals from the embodiments of FIGS. 9 to 12;

FIG. 14 is a block diagram of a random number determining circuit including a plurality of determining blocks according to an embodiment;

FIG. 15 is a circuit diagram of a configuration of a merging block according to an embodiment;

FIG. 16 is a flowchart illustrating a method of operating a random number generating circuit according to an embodiment;

FIG. 17 is a block diagram of a configuration of a random number generator according to an embodiment; and

FIG. 18 is a block diagram of an apparatus including a random number generating circuit according to an embodiment.

### DETAILED DESCRIPTION

Hereinafter, embodiments will be described in detail with reference to the accompanying drawings.

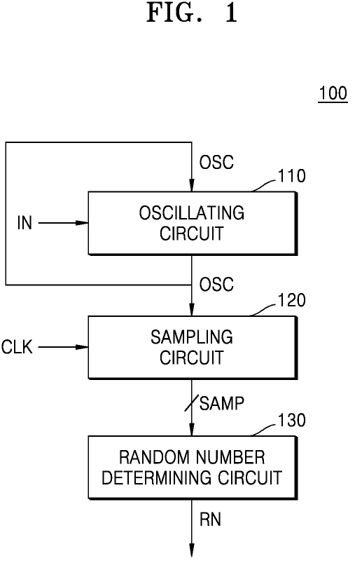

FIG. 1 is a block diagram schematically illustrating a configuration of a random number generating circuit 100 according to an embodiment.

Referring to FIG. 1, the random number generating circuit 100 may include an oscillating circuit 110, a sampling circuit 120, and a random number determining circuit 130. The random number generating circuit 100 may be included in an electronic system to generate a random number RN and provide the random number RN to the electronic system. The electronic system may include, for example, laptop computers, mobile phones, smartphones, tablet PCs, personal digital assistants (PDAs), smart cards, semiconductor packages, and the like.

The oscillating circuit 110 may receive an input signal IN and may generate an oscillation signal OSC based on the input signal and a feedback of the oscillation signal. According to an embodiment, the oscillator circuit 110 may include a ring oscillator. The ring oscillator may include a plurality of inverters, and may generate the oscillation signal OSC that is repeated at a certain period by oscillating through repeated inverted amplification of a plurality of inverters.

The sampling circuit 120 may receive a clock signal CLK, and may generate a plurality of sampling signals SAMP by sampling the oscillation signal OSC based on the clock signal CLK. According to an embodiment, the sampling circuit 120 may include a plurality of delay elements, and may determine a sampling point for sampling the oscillation signal OSC based on a delay signal delayed by some of the plurality of delay elements. The sampling circuit 120 may include only a plurality of inverters or only of a plurality of buffers. However, an embodiment of the disclosure is not limited thereto, and the sampling circuit 120 may be configured by arranging an inverter together with a buffer.

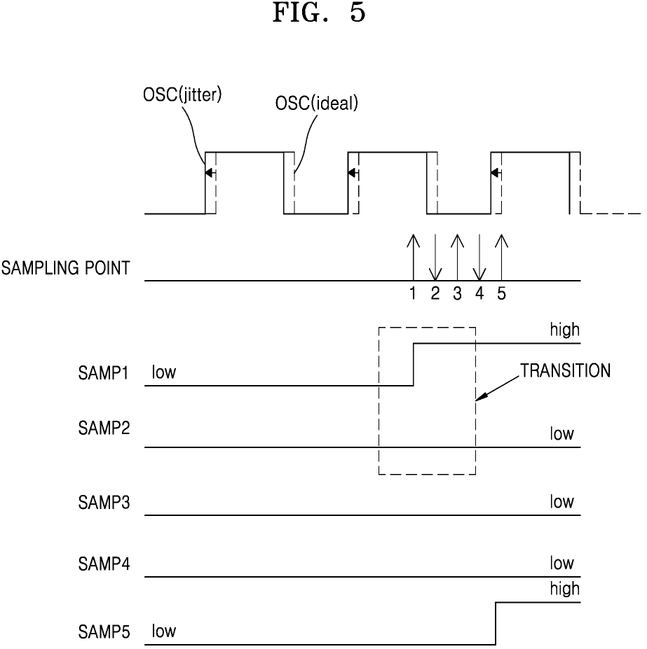

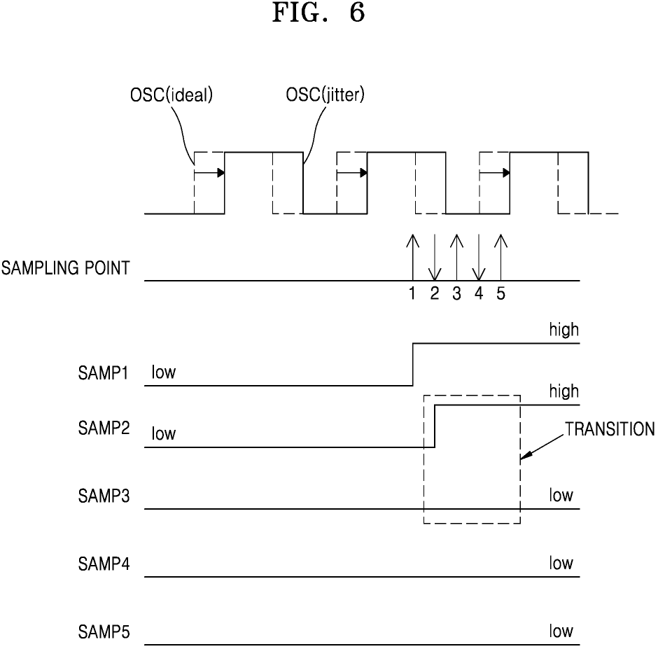

The random number determining circuit 130 according to an embodiment may receive the plurality of sampling signals SAMP, and may determine a logic level of the random number RN from among the plurality of sampling signals SAMP, based on a time point at which the logic level transitions. For example, the random number determining circuit 130 may select, as a target sampling signal SAMP, a sampling signal SAMP in which the first logic level transition occurs from among the plurality of sampling signals SAMP, and may determine a logic level of the random number RN based on the order of the target sampling signal SAMP from among the plurality of sampling signals SAMP. The first logic level transition may be referred to herein as a first-in-time logic level transition. See the dashed box marked “TRANSITION” in FIGS. 5 and 6.

According to an embodiment, when a sampling order of the target sampling signal SAMP is an odd number, a random number RN of a first logic level may be generated, and when a sampling order of the target sampling signal SAMP is an even number, a random number RN of a second logic level may be generated. The first logic level may be a logic low level, and the second logic level may be a logic high level, but an embodiment of the disclosure is not limited thereto. The first logic level may be a logic high level and the second logic level may be a logic low level.

An embodiment of the disclosure for determining a logic level of the random number RN based on a sampling point at which the logic level transitions from among the plurality of sampling signals SAMP may generate the random number RN based on little jitter of the oscillation signal OSC, compared to a comparative circuit in which a logic level of the random number RN is determined according to whether the oscillation signal OSC is jitter advanced or delayed compared to an ideal oscillation signal. Accordingly, the random number generating circuit 100 may generate the random number RN at a higher speed than in the comparative circuit.

In more detail, when the random number generating circuit 100 generates the random number RN by accumulating jitter, the total accumulated jitter may be determined as in Equation 1 by jitter generated within one period and the number of repetitions of the oscillation signal OSC.

$${σ}_{a c c u m u l a t e d} = {σ}_{c y c l e} ∗ \sqrt{\# \_ o f \_ c y c l e}$$

σ_{accumulated} may be accumulated jitter, σ_{accumulated} may be jitter generated within one period, and σ_{accumulated} may be the number of repetitions of the oscillation signal OSC.

Because the accumulated jitter needs to be greater than required jitter needed to generate the random number RN, the number of repetitions of the oscillation signal OSC required to generate the random number RN may be expressed by Equation 2 below.

$${σ}_{a c c u m u l a t e d} \geq {σ}_{n e e d}$$

$$\# \_ o f \_ c y c l e \geq {\left(\frac{{σ}_{n e e d}}{{σ}_{c y c l e}}\right)}^{2}$$

$$\# \_ o f \_ c y c l e = f r e q ∗ t i m e$$

σ_{need} may be the required jitter. In this case, the time required for generating the random number RN may be proportional to the number of repetitions of the oscillation signal OSC, and may be inversely proportional to the frequency of the oscillation signal OSC. That is, as the number of repetitions decreases and the frequency of the oscillation signal OSC increases, the time required for generating the random number RN may be shortened. The performance of the random number generating circuit 100 may be inversely proportional to the time required to generate the random number RN, and may be expressed by Equation 3 below.

$$t i m e \geq \frac{1}{f r e {q}_{R O}} ∗ {\left(\frac{{σ}_{n e e d}}{{σ}_{c y c l e}}\right)}^{2}$$

$$P e r f o r m a n c e ≅ f r e {q}_{R O} ∗ {\left(\frac{{σ}_{c y c l e}}{{σ}_{n e e d}}\right)}^{2}$$

In order to improve the performance of the random number generating circuit 100, it is necessary to increase the frequency of the oscillation signal OSC, increase the jitter within one period of the oscillation signal OSC, or reduce the required jitter. According to an embodiment of the disclosure, the required jitter may be determined by delay times of delay elements included in the sampling circuit 120, and the frequency of the oscillation signal OSC and the jitter within one period of the oscillation signal OSC may be determined by the oscillating circuit 110. That is, because the random number generating circuit 100 may determine the required jitter to be reduced to improve the performance by the sampling circuit 120 configured independently from the oscillating circuit 110, the random number generating circuit 100 may efficiently generate the random number RN.

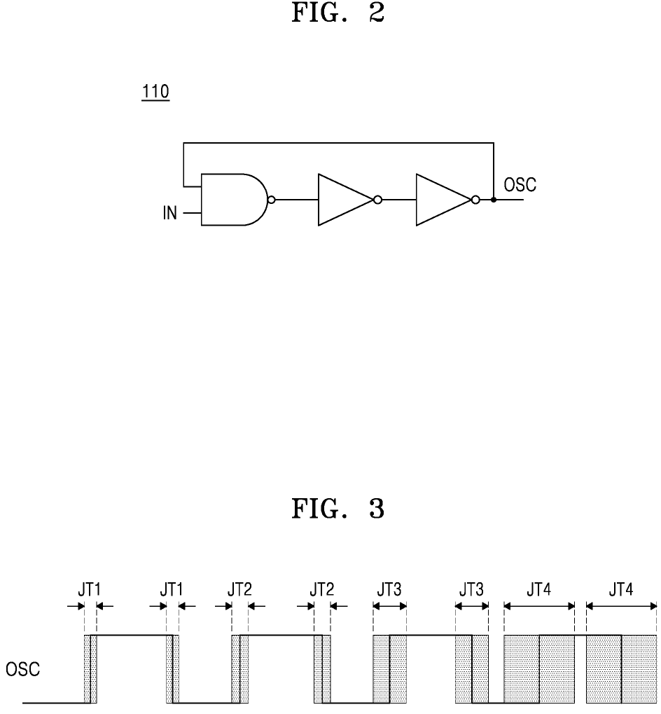

FIG. 2 is a circuit diagram illustrating the oscillating circuit 110 according to an embodiment.

Referring to FIG. 2, a ring oscillator may include a NAND gate and a plurality of inverters. The ring oscillator may receive the input signal IN and an oscillation signal OSC as feedback through the NAND gate. The ring oscillator may generate a repeated oscillation signal OSC based on the oscillation signal OSC received as feedback. The ring oscillator may operate as a noise source that generates jitter.

According to an embodiment, the oscillating circuit 110 may include two inverters, wherein a first inverter may invert the output of the NAND gate, and a second inverter may invert the output of the first inverter. As a result, the ring oscillator may generate the oscillation signal OSC that repeats at a certain period. However, the oscillator circuit 110 is not limited to the configuration shown in FIG. 2, and may include any oscillator that generates jitter accumulated according to the number of repetitions.

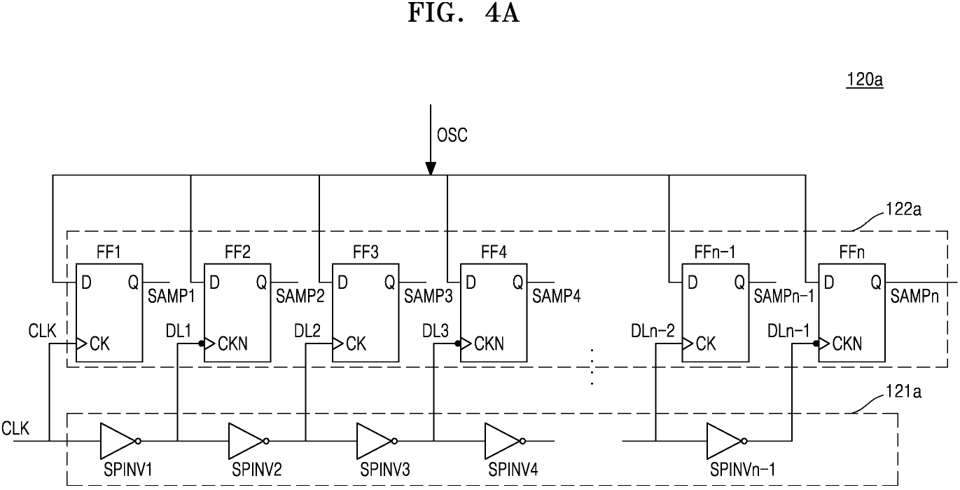

FIG. 3 is a timing diagram of jitter included in the oscillation signal OSC according to an embodiment.

Referring to FIG. 3, the oscillation signal OSC may have jitter accumulated according to the number of repetitions. Jitter may mean that a digital pulse signal waveform is non-constantly changed on a time axis based on an ideal oscillation signal. That is, the oscillating circuit 110 may generate jitter in which an edge is randomly shifted with respect to an edge of an ideal oscillation signal.

For example, the oscillating circuit 110 may start an oscillation operation and generate a clock edge in a first jitter period JT1 (shown with respect to a first rising edge and falling edge of the signal OSC). Thereafter, the oscillating circuit 110 may generate a clock edge in a second jitter period JT2 longer than the first jitter period JT1 by accumulating jitter. Jitter periods JT3 and JT4 are also shown in FIG. 3. As shown in FIG. 3, the oscillating circuit 110 may generate jitter corresponding to a longer time period as the oscillation operation is repeated. For example, the uncertainty of JT4 is higher than that of JT3.

In the random number generating circuit 100, the required jitter is determined by the sampling circuit 120 configured independently from the oscillating circuit 110, and the sampling circuit 120 may perform sampling based on the clock signal CLK oscillating faster than the oscillation signal OSC, so that the random number RN may be generated with only a small amount of jitter.

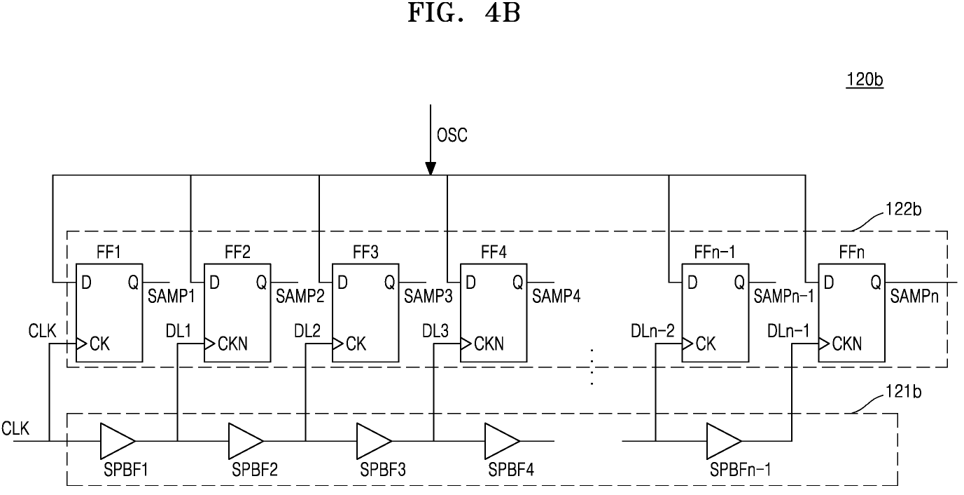

FIGS. 4A and 4B are circuit diagrams of a sampling circuit according to an embodiment.

According to an embodiment, a delay element chain of FIG. 4A may include an inverter chain composed of a plurality of inverters, and a delay element chain of FIG. 4B may include a buffer chain 121b composed of a plurality of buffers. According to FIG. 4A, an output signal with a delayed phase may be generated from an inverted phase with respect to an input signal by an inverter, and according to FIG. 4B, an output signal with a delayed phase may be generated from the same phase as that of an input signal by an inverter.

Referring to FIG. 4A, a sampling circuit 120a may include a sampling inverter chain 121a and a flip-flop chain 122a. In the sampling inverter chain 121a, a plurality of sampling inverters SPINV1 to SPINVn-1 for generating delay signals DL1 to DLn-1 for performing a sampling operation may be connected to each other in series.

In the embodiment of FIG. 4A, the sampling inverters SPINV1 to SPINVn-1 may respectively delay and output the delay signals DL1 to DLn-1 of an inverted phase with respect to an input signal by a certain time. For example, the first sampling inverter SPINV1 may receive the clock signal CLK and output the first delay signal DL1 having a phase inverted with respect to a phase of the clock signal CLK. The second sampling inverter SPINV2 serially connected to the first sampling inverter SPINV1 may receive the first delay signal DL1, and may output the second delay signal DL2 having a phase inverted with respect to a phase of the first delay signal DL1. That is, the second delay signal DL2 generated from the clock signal CLK by the first sampling inverter SPINV1 and the second sampling inverter SPINV2 may have the same phase as that of the clock signal CLK.

The flip-flop chain 122a may receive the oscillation signal OSC through a data terminal by connecting a plurality of flip-flops FF1 to FFn in parallel to a terminal receiving the oscillation signal OSC. Each flip-flop may receive one of the plurality of delay signals and the clock signal CLK generated in the sampling inverter chain 121a in a state of receiving the oscillation signal OSC and may be synchronized with a rising edge or a falling edge to sample the oscillation signal OSC. For example, the first flip-flop FF1 may receive the oscillation signal OSC through the data terminal and may be synchronized with a rising edge of the clock signal CLK to generate a first sampling signal SAMP1.

According to an embodiment, when one sampling inverter SPINV generates a subsequent delay signal DL as in the sampling inverter chain 121a of FIG. 4A, a first flip-flop circuit that performs sampling at a rising edge and a second flip-flop circuit that performs sampling at a falling edge may be alternately arranged in the flip-flop chain 122a. For example, the first flip-flop FF1, the third flip-flop FF3, and the (n-1)^{th} flip-flop (n is a natural number) FFn-1 may be a first flip-flop circuit that performs sampling at a rising edge, and a second flip-flop FF2, the fourth flip-flop FF4, and the n^{th} flip-flop FFn may be the second flip-flop circuit that performs sampling at a falling edge. Accordingly, because the sampling circuit 120a of FIG. 4A may perform sampling at a delay time interval corresponding to one sampling inverter SPINV, less jitter may be required to generate the random number RN.

A random number generating circuit according to a comparative circuit samples the oscillation signal OSC only once and generates the random number RN according to a logic level of the sampled signal, whereas the random number generating circuit 100 may sequentially delay the input clock signal CLK through the plurality of sampling inverters SPINV1 to SPINVn-1 connected to each other in series, and may sample the oscillation signal OSC based on sequentially delayed sampling points. In some embodiments, an interval between the sampling points by the sampling inverters SPINV1 to SPINVn-1 having the minimum delay may have a smaller value than that of the period of the oscillation signal OSC.

In the embodiment of FIG. 4B, each sampling buffer SPBF may delay and output the delay signal DL having the same phase as that of an input signal by a certain time. For example, a first sampling buffer SPBF1 may receive the clock signal CLK and output the first delay signal DL1 having a delayed phase from the same phase as that of the clock signal CLK. A second sampling buffer SPBF2 serially connected to the first sampling buffer SPBF1 may receive the first delay signal DL1, and may output the second delay signal DL2 having a delayed phase from the same phase as that of the first delay signal DL1.

Unlike FIG. 4A, because a phase of an input signal is not reversed in the embodiment of FIG. 4B, the flip-flops FF1 to FFn constituting a flip-flop chain 122b may all be the same type of flip-flops. For example, all of the flip-flops FF1 to FFn of FIG. 4B may perform sampling at a rising edge or may perform sampling at a falling edge.

FIG. 5 is a timing diagram of sampling signals SAMP1 to SAMP5 generated corresponding to respective sampling points when an oscillation signal OSC (jitter) is advanced compared to an ideal oscillation signal OSC (ideal), according to an embodiment, and FIG. 6 is a timing diagram of the sampling signals SAMP1 to SAMP5 generated corresponding to respective sampling points when the oscillation signal OSC (jitter) is delayed, compared to the ideal oscillation signal OSC (ideal), according to an embodiment. In FIG. 5, the sampling time points are numbered 1, 2, 3, 4 and 5.

The sampling circuit 120a may generate the sampling signals SAMP1 to SAMP5 at sampling points corresponding to different time points by a delay element chain. For example, a first sampling point may correspond to a rising edge of the clock signal CLK, and a second sampling point may correspond to a falling edge of the first delay signal DL1 delayed from the clock signal CLK by a delay time.

Referring to FIG. 5, due to jitter, the oscillating circuit 110 may output the oscillation signal OSC (jitter) that is advanced in time, compared to the ideal oscillation signal OSC (ideal). At this time, the first sampling signal SAMP1 generated at the first sampling point may have a logic high level, but because the oscillation signal OSC(jitter) transitions to a logic low level at the second sampling point, the sampling circuit 120a may output the second sampling signal SAMP2 having a logic low level. Because the oscillation signal OSC (jitter) is at a logic low level even at third and fourth sampling points, the sampling circuit 120a may output the third sampling signal SAMP3 and the fourth sampling signal SAMP4 having a logic low level. Because the oscillation signal OSC transitions back to a logic high level at the fifth sampling point, the sampling circuit 120a may output the fifth sampling signal SAMP5 having a logic high level.

Referring to FIG. 6, due to jitter, the oscillating circuit 110 may output the oscillation signal OSC (jitter) that is delayed in time, compared to the ideal oscillation signal OSC (ideal). At this time, the first sampling signal SAMP1 and the second sampling signal SAMP2 sampled at the first sampling point and the second sampling point may have a logic high level, but because the oscillation signal OSC (jitter) transitions to a logic low level at a third sampling point, the sampling circuit 120a may output the third sampling signal SAMP3 having a logic low level. Because the oscillation signal OSC is at a logic low level even at fourth and fifth sampling points, the sampling circuit 120a may output the fourth sampling signal SAMP4 and the fifth sampling signal SAMP5 having a logic low level.

The random number determining circuit 130 may determine a logic level of the random number RN based on a target sampling signal in which the first logic level transition occurs from among the plurality of sampling signals SAMP. According to an embodiment, the random number determining circuit 130 may determine a logic level of the random number RN according to whether the order of the sampling signal SAMP in which the first logic level transition occurs is odd or even.

For example, in the embodiment of FIG. 5, the logic level is first changed in the second sampling signal SAMP2 from among the plurality of sampling signals SAMP1 to SAMP5, and in the embodiment of FIG. 6, the logic level is first changed in the third sampling signal SAMP3. At this time, in the embodiment of FIG. 5, the random number determining circuit 130 may output the random number RN of a second logic level because the first logic level transition occurs in an even-numbered sampling signal, and in the embodiment of FIG. 6, the random number determining circuit 130 may output the random number RN of a first logic level because the first logic level transition occurs in an odd-numbered sampling signal.

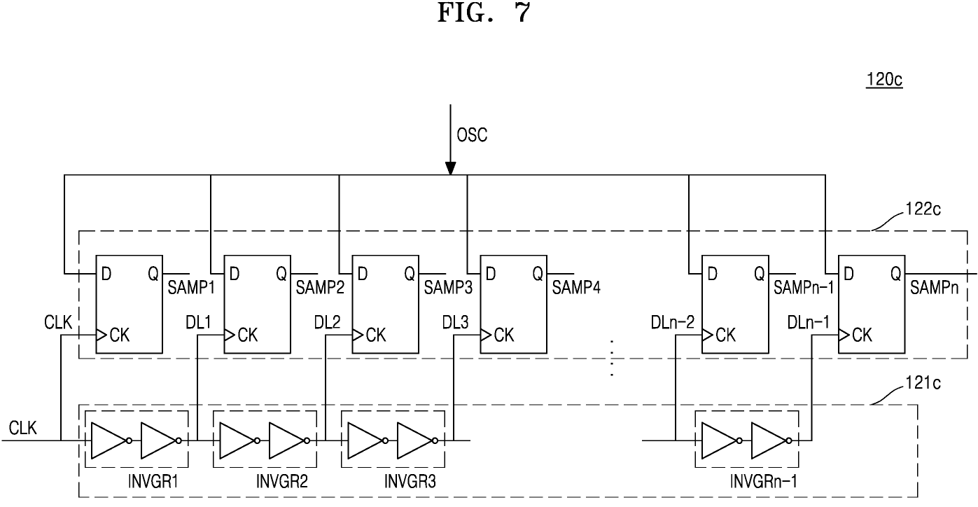

FIG. 7 is a circuit diagram of a sampling circuit 120c according to another embodiment.

Referring to FIG. 7, a sampling inverter chain 121c of the sampling circuit 120c according to another embodiment may include a plurality of inverter groups INVGR1 to INVGRn-1, and each of the inverter groups INVGR1 to INVGRn-1 may include an even number of sampling inverters. Because the inverter groups INVGR1 to INVGRn-1 include an even number of sampling inverters, signals input and output to/from the inverter groups INVGR1 to INVGRn-1 may have only a difference as much as a delayed phase corresponding to the sampling inverters.

For example, when the first inverter group INVGR1 receives the clock signal CLK and outputs the first delay signal DL1, a phase between the clock signal CLK and the first delay signal DL1 may have only a difference as much as a delayed phase due to two sampling inverters. Similarly, the second delay signal DL2 to the (n-1)^{th} delay signal DLn-1 may be different from each other by a delayed phase with respect to the preceding delay signal.

A flip-flop chain 122c according to the embodiment of FIG. 7 may include only flip-flops of the same type. For example, all flip-flops of the flip-flop chain 122c may be configured to sample the oscillation signal OSC only at a rising edge or sample the oscillation signal OSC only at a falling edge.

Compared with the embodiment of FIG. 4A, because the sampling circuit 120c of the embodiment of FIG. 7 may generate delay signals having a delayed phase with respect to the preceding delay signal through at least two sampling inverters, the interval between sampling points may be greater than in the embodiment of FIG. 4A. However, the embodiment of FIG. 7 may prevent data of sampling signals SAMP1 to SAMPn from being biased.

In the embodiment of FIG. 4A, a flip-flop sampling the oscillation signal OSC at a rising edge and a flip-flop sampling the oscillation signal OSC at a falling edge are alternately arranged, and a time difference between a rising edge and a falling edge generated by the sampling inverter SPINV or a difference according to a flip-flop type may affect a ratio of the random number RN. For example, in the embodiment of FIG. 4A, an interval between the rising edge of the clock signal CLK and the falling edge of the first delay signal DL1 may not exactly match an interval between the falling edge of the first delay signal DL1 and the rising edge of the second delay signal DL2. Accordingly, the probability that the random number generating circuit 100 generates the random number RN of a logic high level does not exactly match the probability that the random number generating circuit 100 generates the random number RN of a logic low level, so that the randomness of the random number generating circuit 100 may be lowered.

In contrast, because the flip-flops of the embodiment of FIG. 7 may all perform sampling of the oscillation signal OSC at the same rising edge or falling edge, all intervals between the clock signal CLK and the delay signals DL1 to DLn-1 may be constant. Accordingly, the probability that the random number generating circuit 100 generates the random number RN of a logic high level may be equal to the probability that the random number generating circuit 100 generates the random number RN of a logic low level.

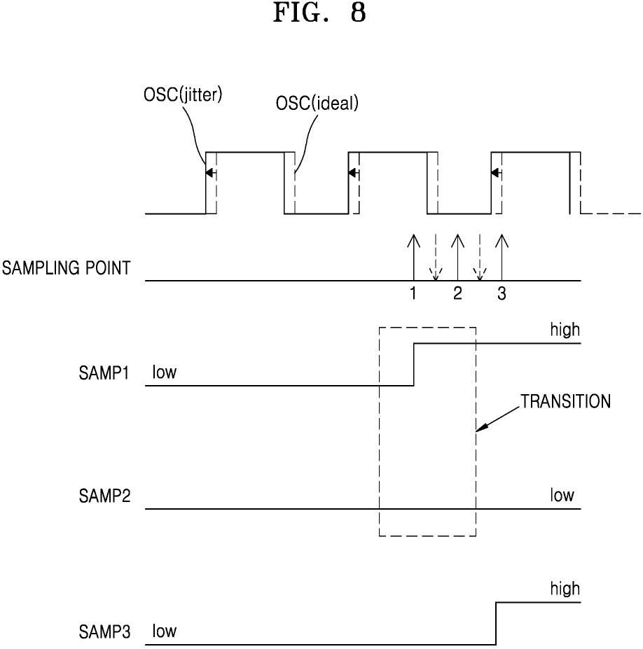

FIG. 8 is a timing diagram illustrating an example in which the sampling signals SAMP are generated corresponding to each sampling point based on the oscillation signal OSC (jitter) generated according to the embodiment of FIG. 7.

Referring to FIG. 8, unlike the timing diagrams of FIGS. 5 and 6, the sampling circuit 120b may perform a sampling operation when the clock signal CLK and the delay signals DL1 to DLn-1 form a rising edge. Referring to FIGS. 7 and 8, each of the delay signals DL1 to DLn-1 may be a signal delayed by two delay elements, an interval between the sampling points may be doubled, compared to the embodiments of FIGS. 5 and 6.

Due to jitter, the oscillation circuit 110 may output the oscillation signal OSC (jitter) that is advanced in time, compared to the ideal oscillation signal OSC (ideal). At this time, the first sampling signal SAMP1 generated at the first sampling point may have a logic high level, but because the oscillation signal OSC (jitter) transitions to a logic low level at the second sampling point, the sampling circuit 120b may output the second sampling signal SAMP2 having a logic low level. Because the oscillation signal OSC transitions back to a logic high level at the third sampling point, the sampling circuit 120b may output the third sampling signal SAMP3 having a logic high level.

The random number determining circuit 130 may determine a logic level of the random number RN according to whether the order of the sampling signal SAMP in which the first logic level transition occurs is odd or even. For example, in the embodiment of FIG. 8, because the logic level is first changed in the second sampling signal SAMP2 from among the plurality of sampling signals SAMP1 to SAMP3, the random number RN of a second logic level may be output.

According to another embodiment, the random number determining circuit 130 may determine the order of the sampling signals SAMP in which the first logic level transition occurs, and may output a code corresponding to the determined order of the sampling signals SAMP as the random number RN. When the random number generating circuit 100 determines the order of a target sampling signal in which the first logic level transition occurs, the random number generating circuit 100 may request a code corresponding to the order of the target sampling signal from a memory device that stores a code corresponding to each sampling point. For example, when sampling is performed 17 times, the second sampling signal SAMP2 to a seventeenth sampling signal SAMP17 may be mapped to different 4-bit codes, respectively, and one of the second sampling signal SAMP2 to the seventeenth sampling signal SAMP17 may be selected as a target sampling signal. The random number determining circuit 130 may output, as the random number RN, code '0001' when the second sampling signal SAMP2 is the target sampling signal, code '1110' when the third sampling signal SAMP3 is the target sampling signal, code '0010' when the fourth sampling signal SAMP4 is the target sampling signal, and code '1101' when the fifth sampling signal SAMP5 is the target sampling signal.

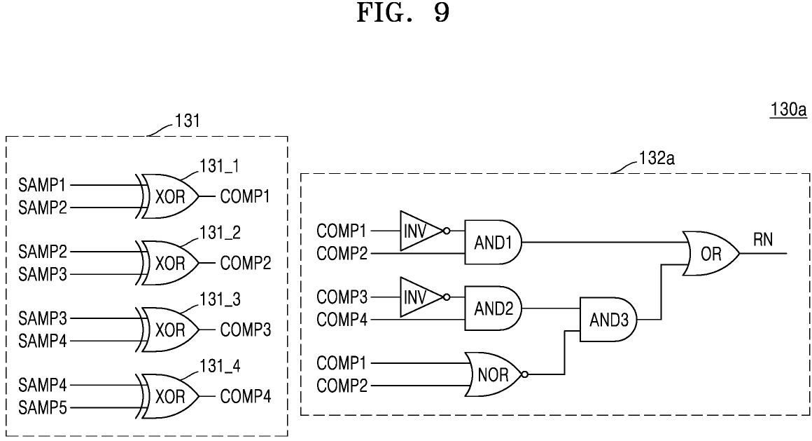

FIGS. 9 to 12 are circuit diagrams of examples of the random number determining circuit 130 according to different embodiments.

Referring to FIGS. 9 to 12, the random number determining circuit 130 may include a comparator array 131 including a plurality of comparators 131_1 to 131_4 and a determination circuit 132a, 132b, 132c or 132d.

Each of the plurality of comparators 131_1 to 131_4 may receive two sampling signals SAMP and generate comparison results COMP1 to COMP4 with respect to the sampling signals SAMP1 to SAMP5. For example, the comparators 131_1 to 131_4 may be configured as XOR gates, and may determine a logic level of a comparison result COMP according to whether logic levels of the two sampling signals SAMP match. For example, the comparators 131_1 to 131_4 may output a comparison result COMP of a logic low level when both of the two sampling signals SAMP have a logic low level or a logic high level, and may output a comparison result COMP of a logic high level when the logic levels of the two sampling signals SAMP are different from each other.

According to an embodiment, the comparators 131_1 to 131_4 may receive sampling signals SAMP of two adjacent sampling points. That is, the two sampling signals SAMP may be a sampling signal SAMP at an odd-numbered sampling point and a sampling signal SAMP at an even-numbered sampling point. For example, a first comparator 131_1 included in the comparator array 131 may compare logic levels of the first sampling signal SAMP1 and the second sampling signal SAMP2 to each other and output the first comparison result COMP1 of a logic high level when the logic levels are the same as each other. Similarly, a second comparator 131_2 may compare logic levels of the second sampling signal SAMP2 and the third sampling signal SAMP3 to each other to output the second comparison result COMP2. A third comparator 131_3 may compare logic levels of the third sampling signal SAMP3 and the fourth sampling signal SAMP4 to each other to output the third comparison result COMP3, and a fourth comparator 131_4 may compare logic levels of the fourth sampling signal SAMP4 and the fifth sampling signal SAMP5 to each other to output the fourth comparison result COMP4.

Because the comparators 131_1 to 131_4 configured as XOR gates output a comparison result of a logic high level in response to the sampling signals SAMP having different logic levels, the comparators 131_1 to 131_4 may output a comparison result COMP of a logic high level when a logic level transitions with respect to the sampling signals SAMP at the previous sampling point.

According to an embodiment, the comparator array 131 may include a first group of comparators that compare an odd-sampled signal sampled in an odd-numbered sampling order with an even-sampled signal in the next sampling order for the odd-sampled signal, and a second group of comparators that compare an even-sampled signal sampled in an even-numbered sampling order with an odd-numbered sampling order in the next sampling order for the even-sampled signal.

When the comparison result of a logic high level is output from one of the comparators 131_1 and 131_3 in the first group of comparators, it may mean that the logic level of the sampling signal SAMP transitions in the even-numbered sampling order, and when the comparison result of a logic high level is output from one of the comparators 131_2 and 131_4 in the second group of comparators, it may mean that the logic level of the sampling signal SAMP transitions in the odd-numbered sampling order. Accordingly, when all the comparators 131_1 and 131_3 in the first group of comparators output a comparison result of a logic low level, and at least one of the comparators 131_2 and 131_4 in the second group of comparators outputs a comparison result of a logic high level, the random number generating circuit 100 may output the random number RN of a first logic level. When all the comparators 131_2 and 131_4 in the second group of comparators output a comparison result of a logic low level, and at least one of the comparators 131_1 and 131_3 in the first group of comparators outputs a comparison result of a logic high level, the random number generating circuit 100 may output the random number RN of a second logic level.

The determination circuit 132 may determine a sampling signal SAMP of a sampling order in which logic level transition is the earliest when at least one comparator in the first group of comparators outputs a logic high level comparison result and at least one comparator in the second group of comparators outputs a logic high level comparison result. That is, the determination circuit 132 may generate, as the random number RN, a comparison result having a logic high level in the earliest order from among the plurality of comparison results COMP1 to COMP4.

Referring to FIG. 9, a first AND gate AND1 may receive an inverted signal of the first comparison result COMP1 and the second comparison result COMP2, and may output a logic high level signal when both the inverted signal of the first comparison result COMP1 and the second comparison result COMP2 have a logic high level. That is, the first AND gate AND1 may output a logic low level when the first logic level transition occurs in the second sampling signal SAMP2, and may output a logic high level when the first logic level transition occurs in the third sampling signal SAMP3. Accordingly, through a subsequent OR gate OR, the random number generating circuit 100 may output the random number RN of a logic high level when the first logic level transition occurs in the third sampling signal SAMP3 that is the odd-sampled signal.

A NOR gate NOR may receive the first comparison result COMP1 and the second comparison result COMP2, and may output a logic high level signal when both the first comparison result COMP1 and the second comparison result COMP2 have a logic low level. That is, when all of the first sampling signal SAMP1 to the third sampling signal SAMP3 are maintained at the same logic level, the NOR gate NOR may output a logic high level, and the first AND gate AND1 may output a logic low level.

A second AND gate AND2 may receive an inverted signal of the third comparison result COMP3 and the fourth comparison result COMP4, and may output a logic high level signal when both the inverted signal of the third comparison result COMP3 and the fourth comparison result COMP4 have a logic high level. That is, the second AND gate AND2 may output a logic low level when the first logic level transition occurs in the fourth sampling signal SAMP4, and may output a logic high level when the first logic level transition occurs in the fifth sampling signal SAM5.

A third AND gate AND3 may receive an output signal of the NOR gate NOR and an output signal of the second AND gate AND2, and may output a logic high level when both the output signal of the NOR gate NOR and the output signal of the second AND gate AND2 have a logic high level. That is, the third AND gate AND3 may output, through the NOR gate NOR, an AND operation result of the third comparison result COMP3 and the fourth comparison result COMP4 when the first sampling signal SAMP1 to the third sampling signal SAMP3 are all maintained at the same logic level. That is, the third AND gate AND3 may output a logic low level when the first logic level transition occurs in the fourth sampling signal SAMP4, and may output a logic high level when the first logic level transition occurs in the fifth sampling signal SAMP5.

The OR gate OR may generate the random number RN of a logic high level when at least one of an output signal of the first AND gate AND1 and an output signal of the third AND gate AND3 has a logic high level. Accordingly, a determination circuit 132a may generate the random number RN of a logic low level when the first logic level transition occurs in the second sampling signal SAMP2 and the fourth sampling signal SAMP4, and may generate a logic high level random number RN when the first logic level transition occurs in the third sampling signal SAMP3 and the fifth sampling signal SAMP5.

Although the embodiment in which a random number determining circuit 130a of FIG. 9 determines the random number RN based on the five sampling signals SAMP1 to SAMP5 has been exemplarily described, in an embodiment of the disclosure, the number of sampling signals is not limited thereto.

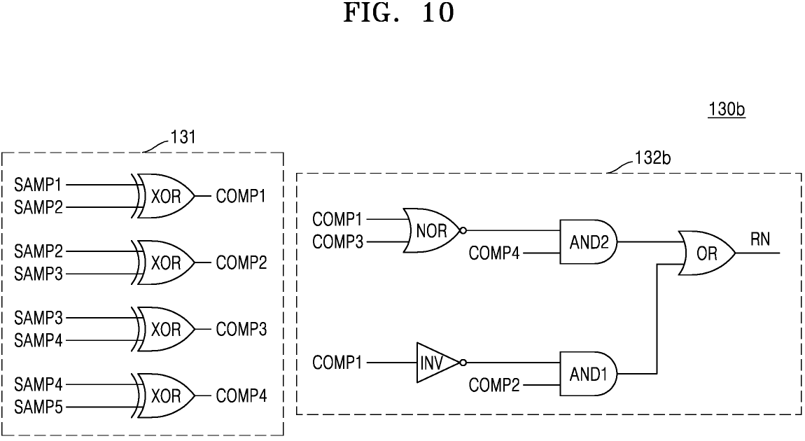

Referring to FIG. 10, the first AND gate AND1 may receive the inverted signal of the first comparison result COMP1 and the second comparison result COMP2, and may output a logic high level signal when both the inverted signal of the first comparison result COMP1 and the second comparison result COMP2 have a logic high level. That is, the first AND gate AND1 may output a logic low level when the first logic level transition occurs in the second sampling signal SAMP2, and may output a logic high level when the first logic level transition occurs in the third sampling signal SAMP3. Accordingly, through a subsequent OR gate OR, the random number generating circuit 100 may output the random number RN of a logic high level when the first logic level transition occurs in the third sampling signal SAMP3 that is the odd-sampled signal.

The NOR gate NOR may receive the first comparison result COMP1 and the second comparison result COMP2, and may output a logic high level signal when both the first comparison result COMP1 and the second comparison result COMP2 have a logic low level. That is, when the logic level does not transition in an even-sampled signal that is the second sampling signal SAMP2 and the fourth sampling signal SAMP4, the NOR gate NOR may output a logic high level signal.

The second AND gate AND2 may receive the output signal of the NOR gate NOR and the fourth comparison result COMP4, and may determine the output signal of the second AND gate AND2 according to a logic level of the fourth comparison result COMP4 when the logic level does not transition in the even-sampled signal. That is, when the first logic level transition occurs in the fifth sampling signal SAMP5, the second AND gate AND2 may output a logic high level, and the random number generating circuit 100 may output the random number RN of a logic high level through the subsequent OR gate OR.

Although the embodiment in which a random number determining circuit 130b according to the embodiment of FIG. 10 determines the random number RN based on the five sampling signals SAMP1 to SAMP5 has been exemplarily described, in the embodiment of the disclosure, the number of sampling signals SAMP is not limited thereto.

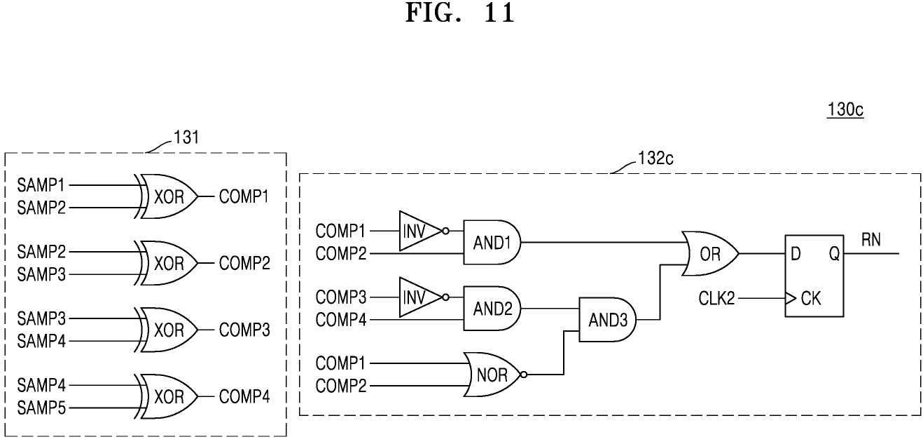

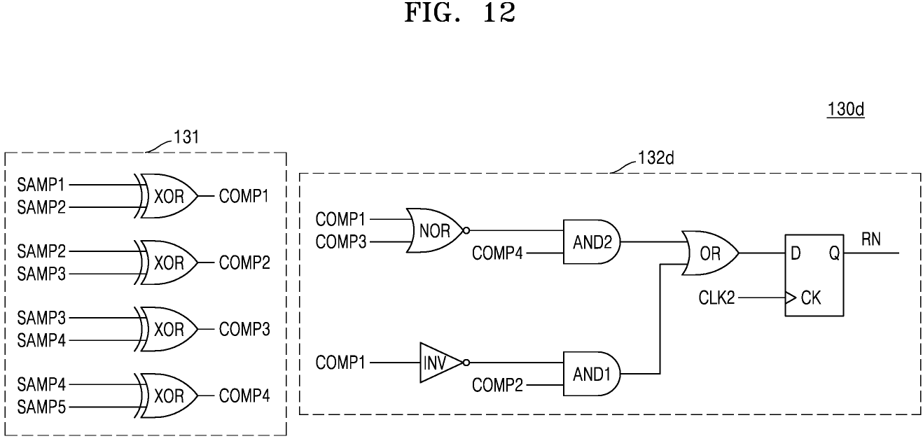

Referring to FIGS. 11 and 12, the determination circuit may further include a flip-flop for outputting an output signal of the OR gate OR as the random number RN in synchronization with a second clock signal CLK2 in the determination circuits 130a and 130b of FIGS. 9 and 10. FIG. 11 includes a random number determining circuit 130c. FIG. 12 includes a random number determining circuit 130d. The logic level of the second clock signal CLK2 may transition corresponding to a sampling period in which the random number generating circuit 100 performs a plurality of sampling operations. For example, when the random number generating circuit 100 performs sampling five times to generate one random number RN, a rising edge or a falling edge of the second clock signal CLK2 may be formed to correspond to five sampling points.

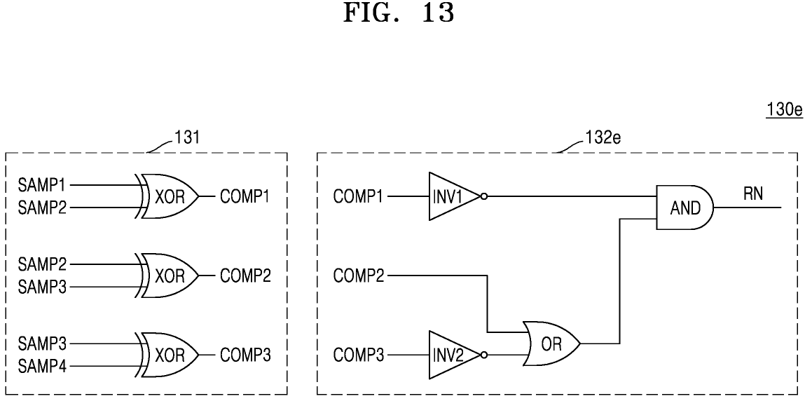

FIG. 13 is a circuit diagram of the random number determining circuit 130e that generates the random number RN when the random number determining circuit 130 receives different numbers of sampling signals SAMP from the embodiments of FIGS. 9 to 12.

Referring to FIG. 13, the random number determining circuit 130e may receive a different numbers of sampling signals SAMP1 to SAMP4 from FIGS. 9 to 12. For example, the embodiments of FIGS. 9 to 12 may determine a logic level of the random number RN by receiving the five sampling signals SAMP1 to SAMP5, and the embodiment of FIG. 13 may determine a logic level of the random number RN by receiving the four sampling signals SAMP1 to SAMP4.

The comparator array 131 according to an embodiment may include comparators configured with three XOR gates. Each comparator may compare the sampling signals SAMP1 to SAMP4 at adjacent sampling points. The comparator may output the comparison results COMP1 to COMP3 of a logic low level when two sampling signals have a logic low level or a logic high level, and may output the comparison results COMP1 to COMP3 of a logic high level when the logic levels of the two sampling signals are different from each other.

A determination circuit 132e may generate the random number RN based on the first comparison results COMP1 to the third comparison results COMP3 generated by the comparator array 131. An AND gate AND of the determination circuit 132e may receive the inverted signal of the first comparison result COMP1 and the output signal of the OR gate OR. That is, when the logic level of the second sampling signal SAMP2 transitions with respect to the first sampling signal SAMP1, the first comparison result COMP1 of a logic high level is output, so that the AND gate AND may generate the random number RN of a logic low level.

The OR gate OR may receive inverted signals of the second comparison result COMP2 and the third comparison result COMP3, and may output a logic high level when any inverted signals of the second comparison result COMP2 and the third comparison result COMP3 has a logic high level. That is, when the first logic level transition occurs in the third sampling signal SAMP3, the inverted signal of the first comparison result COMP1 has a logic high level and the OR gate OR outputs a logic high level, and thus, the AND gate AND may generate the random number RN of a logic high level. When the first logic level transition occurs in the fourth sampling signal SAMP4, the OR gate OR outputs a logic low level, and thus, the AND gate AND may generate the random number RN of a logic low level.

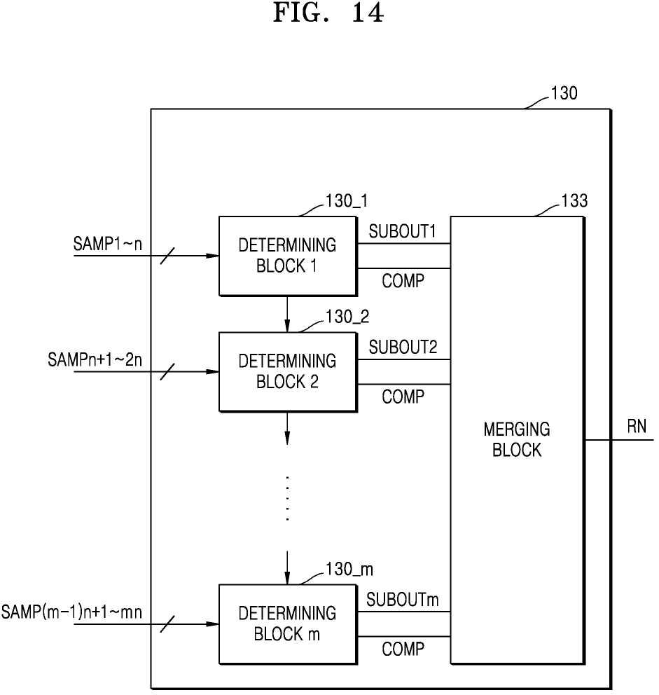

FIG. 14 is a block diagram of the random number determining circuit 130 including a plurality of determining blocks according to an embodiment.

Referring to FIG. 14, the random number determining circuit 130 may include a plurality of determining blocks 130_1 to 130_m. The determining blocks 130_1 to 130_m may receive different sampling signals SAMP, respectively, and the random number determining circuit 130 may generate one of signals SUBOUT1 to SUBOUTm respectively generated by the determining blocks 130_1 to 130_m as the random number RN.

According to an embodiment, the random number determining circuit 130 may include the first determining block to the m^{th} determining block (130_1 to 130_m, m is a natural number), and each determining block may receive n sampling signals SAMP. Each of the determining blocks 130_1 to 130_m may be configured by one of the circuits of FIGS. 9 to 13. Because the circuits of FIGS. 9 to 13 may generate the random number RN by receiving the five sampling signals SAMP1 to SAMP5, the random number determining circuit 130 including the plurality of determining blocks 130_1 to 130_m may receive sampling signals SAMP of a multiple of 5 and generate the random number RN.

According to an embodiment, the first to m^{th} determining blocks 130_1 to 130_m may receive sampling signals SAMP in the order of sampling points. For example, the first sampling signal SAMP1 to the n^{th} sampling signal SAMPn received by the first determining block 130_1 may be signals sampled at n sampling points after sampling operations start.

The random number determining circuit 130 may deactivate a subsequent determining block when the logic level of the sampling signal SAMP transitions in the preceding determining block, and may generate the random number RN by the determining block to which the logic level transitions. For example, when the first determining block 130_1 determines that logic levels of the n sampling signals SAMP1 to SAMPn do not transition, the random number determining circuit 130 may activate the second determining block 130_2 to determine whether logic levels of n sampling signals SAMPn+1 to SAMP2n transition again. When the second determining block 130_2 determines that there is a sampling signal to which the logic level transitions from among the sampling signals SAMPn+1 to SAMP2n, the random number determining circuit 130 may deactivate the third to m^{th} determining blocks 130_3 to 130_m and finally output the random number RN determined by the second determining block 130_2.

The determining blocks 130_1 to 130_m of FIG. 14 may receive all n sampling signals, but the number of sampling signals received by the determining blocks 130_1 to 130_m is not limited thereto, and different numbers of sampling signals may be received for each of the determining blocks 130_1 to 130_m. As shown in FIG. 14, determining block 1 receives sampling signals SAMP1 to SAMPn. Determining block 2 receives sampling signals SAMPn+1 to SAMP2n. The final determining block, determining block m, receives sampling signals SAMP(m-1) to SAMPmn.

According to an embodiment, the random number determining circuit 130 may further include a merging block 133, and the merging block 133 may generate the random number RN by receiving the sub-output signals SUBOUT1 to SUBOUTm and the comparison results COMP from the determining blocks 130_1 to 130_m, respectively. The sub-output signals SUBOUT1 to SUBOUTm, which are signals generated as the random number RN in FIGS. 9 to 13, may be provided to the merging block 133, and the comparison results COMP generated by comparator arrays may be provided to the determination circuit 132 and the merging block 133.

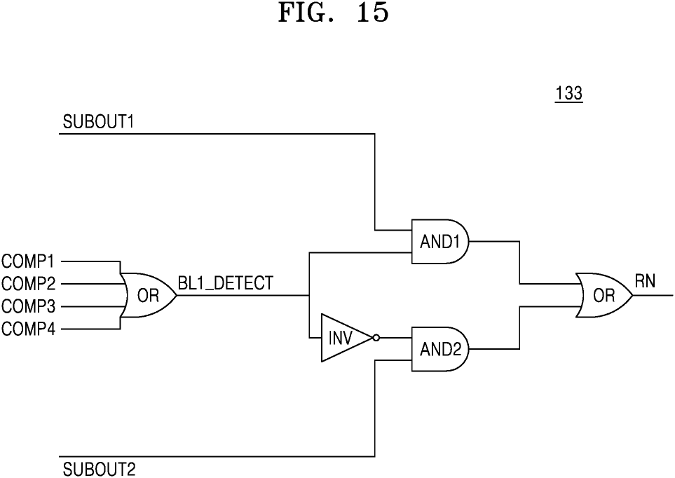

According to an embodiment, the merging block 133 may generate one of the plurality of sub-output signals SUBOUT1 to SUBOUTm as the random number RN based on the comparison results COMP received from the determining blocks 130_1 to 130_m, respectively. The determining blocks 130_1 to 130_m may determine whether a transition occurs among the sampling signals SAMP respectively received by the determining blocks 130_1 to 130_m by receiving the comparison results COMP from the comparator array included in a previous determining block. For example, when a transition of the sampling signal SAMP does not occur, all comparators of XOR gates included in the comparator array may output a logic low level. That is, the determining blocks 130_1 to 130_m may not determine whether a transition occurs among sampling signals that are deactivated and received when at least one of the comparison results COMP generated in the previous determining block has a logic high level. Hereinafter, a method, performed by the merging block 133, of generating one of a plurality of sub-output signals as the random number RN is described with reference to FIG. 15.

FIG. 15 is a circuit diagram illustrating a configuration of the merging block 133 according to an embodiment.

Referring to FIG. 15, the merging block 133 may receive sub-output signals SUBOUT1 and SUBOUT2 from two determining blocks, and may receive the comparison results COMP1 to COMP4 from the preceding determining block. The preceding determining block may be a block for receiving sampling signals sampled at a sampling point that precedes sampling signals respectively received by the plurality of determining blocks 130_1 to 130_m. For example, when the merging block 133 receives the first sub-output signal SUBOUT1 and the second sub-output signal SUBOUT2 from the first determining block 130_1 and the second determining block 130_2, the merging block 133 may receive the comparison results COMP1 to COMP4 from the first determining block 130_1.

The merging block 133 may determine, through an OR gate OR, whether at least one of the first to fourth comparison results COMP1 to COMP4 of the first determining block 130_1 has a logic high level. When logic levels of the first to fifth sampling signals SAMP1 to SAMP5 received by the first determining block 130_1 do not transition, all of the first to fourth comparison results COMP1 to COMP4 have a logic low level, and thus, the OR gate OR may output a first transition detection signal BL1 DETECT having a logic low level. The first transition detection signal BL1 DETECT is a signal indicating whether the sampling signal SAMP transitions in the first determining block 130_1, and may indicate that a transition of the sampling signal SAMP occurs in the first determining block 130_1 when the first transition detection signal BL1_DETECT has a logic high level, and a transition of the sampling signal SAMP does not occur in the first determining block 130_1 when the first transition detection signal BL1_DETECT has a logic low level.

The merging block 133 may generate the first sub-output signal SUBOUT1 as the random number RN through the first AND gate AND1 when the first transition detection signal BL1 DETECT has a logic high level, and may generate the second sub-output signal SUBOUT2 as the random number RN through the second AND gate AND2 when the first transition detection signal BL1_DETECT has a logic low level.

The embodiment of FIG. 15 has described a method of generating a random number RN based on the sub-output signals SUBOUT1 and SUBOUT2 of the two determining blocks, but the merging block may include all embodiments of generating one of the sub-output signals as a random number RN based on comparison results of three or more determining blocks.

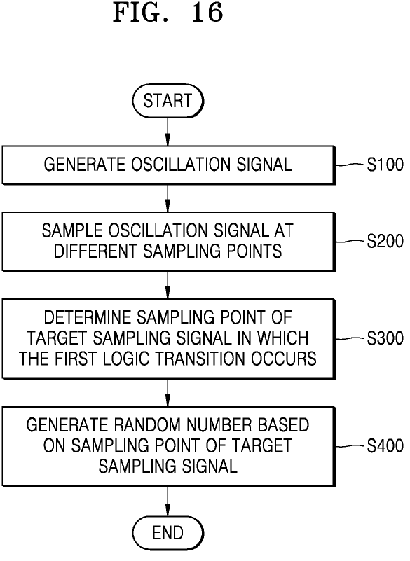

FIG. 16 is a flowchart illustrating a method of operating the random number generating circuit 100 according to an embodiment.

Referring to FIG. 16, the random number generating circuit 100 may generate the oscillation signal OSC that accumulates jitter, and may generate the random number RN by determining a time point at which logic levels of sampling signals SAMP generated by sampling the oscillation signal OSC a plurality of times transition. For example, the random number generating circuit 100 may determine the logic level of the random number RN according to whether a sampling point at which logic levels of the sampling signals SAMP first transition is odd or even.

In operation S100, the random number generating circuit 100 may generate the oscillation signal OSC that repeatedly oscillates at a certain period. According to an embodiment, the random number generating circuit 100 may include a ring oscillator and generate the oscillation signal OSC through a plurality of delay elements included in the ring oscillator.

In operation S200, the random number generating circuit 100 may sample the oscillation signal OSC at different sampling points. A delay element chain including the plurality of delay elements included in the random number generating circuit 100 may generate delay signals corresponding to different sampling points. The delay signals may be provided to a plurality of flip-flops, respectively, and each of the flip-flops may receive the oscillation signal OSC and sample the oscillation signal OSC at a rising edge or a falling edge of each of the delay signals.

In operation S300, the random number generating circuit 100 may determine a sampling point of a target sampling signal SAMP to which the first logic level transition occurs from among the plurality of generated sampling signals SAMP. A comparator array included in the random number generating circuit 100 may include a plurality of comparators configured as XOR gates. Each of the comparators may compare sampling signals SAMP between adjacent sampling points, and may output a comparison result of a logic high level when the sampling signals SAMP have different logic levels, that is, when logic levels of the sampling signals SAMP transition. Accordingly, the random number generating circuit 100 may determine a sampling signal SAMP to which a logic level transitions with respect to a previous sampling signal SAMP from among the plurality of sampling signals SAMP.

At this time, a determination circuit included in the random number generating circuit 100 may determine a sampling point at which a logic level first transitions based on comparison results generated by the comparators.

In operation S400, the random number generating circuit 100 may generate the random number RN based on the sampling point of the target sampling signal SAMP. According to an embodiment, the random number generating circuit 100 may determine a logic level of the random number RN according to whether the sampling point of the target sampling signal SAMP is an even number or an odd number from among a plurality of sampling points. According to another embodiment, the random number generating circuit 100 may output a mapped code as the random number RN according to the order of sampling points.

The random number generating circuit 100 that generates the random number RN by jitter of the oscillation signal OSC needs to simultaneously consider generating a lot of jitter of the oscillation signal OSC and reducing the amount of jitter required for generating the random number RN to determine fast performance. According to a comparative circuit, the amount of jitter may be increased by designing a ring oscillator for generating the oscillation signal OSC to be slow, but in this case, the amount of jitter required increases, limiting performance improvement. When a ring oscillator is designed quickly to reduce the amount of jitter required, the jitter generated will be smaller, which also limits performance improvement.

In contrast, the random number generating circuit 100 may independently configure a ring oscillator generating jitter and a circuit determining jitter required for generating the random number RN, so that the ring oscillator may be designed to generate a lot of jitter, and may maximize performance by designing the smallest amount of jitter required to generate the random number RN regardless of the ring oscillator.

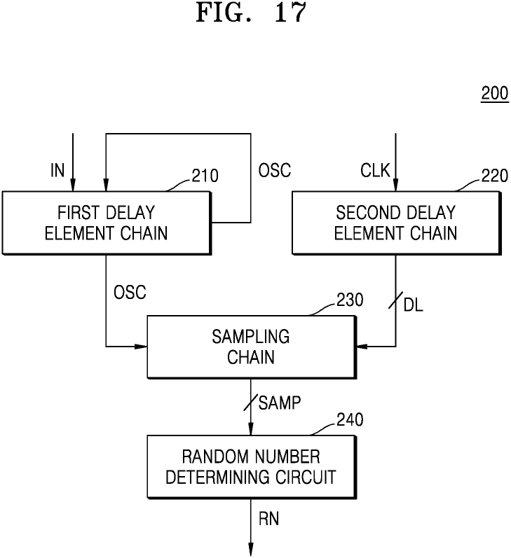

FIG. 17 is a block diagram schematically illustrating a configuration of the random number generator 200 according to an embodiment.

Referring to FIG. 17, the random number generator 200 may include a first delay element chain 210, a second delay element chain 220, a sampling chain 230, and a random number determining circuit 240. The first delay element chain 210 may generate the oscillation signal OSC in response to the input signal IN, and may receive the output oscillation signal OSC as feedback. That is, the first delay element chain 210 may continuously generate the oscillation signal OSC that repeatedly oscillates according to a feedback result of the output oscillation signal OSC.

The second delay element chain 220 may receive the clock signal CLK having a rising edge and a falling edge every certain period, and may generate delay signals DL having phases delayed by different delay times with respect to the clock signal CLK. According to an embodiment, each of a plurality of delay elements included in the second delay element chain 220 may generate a delay signal delayed by a certain phase with respect to the input signal IN.

The sampling chain 230 may receive the plurality of delay signals DL generated by the second delay element chain 220 and the oscillation signal OSC generated by the first delay element chain 210, and may sample the oscillation signal OSC according to a rising edge or a falling edge of each of the plurality of delay signals DL. Jitter of the oscillation signal OSC may be randomly generated, a sampling point corresponding to a rising edge or a falling edge of the oscillation signal OSC from among a plurality of sampling points may also be randomly generated. That is, a time point at which a logic level transitions among the sampling signals SAMP may be randomly generated.

The random number determining circuit 240 may receive the sampling signals SAMP, and may determine a logic level of the random number RN based on the sampling signal SAMP to which the logic level transitions among the sampling signals SAMP. According to an embodiment, the random number determining circuit 240 may determine the logic level of the random number RN according to whether an order of a sampling point to which a logic level transitions from among sampling points corresponding to the sampling signals SAMP is even or odd.

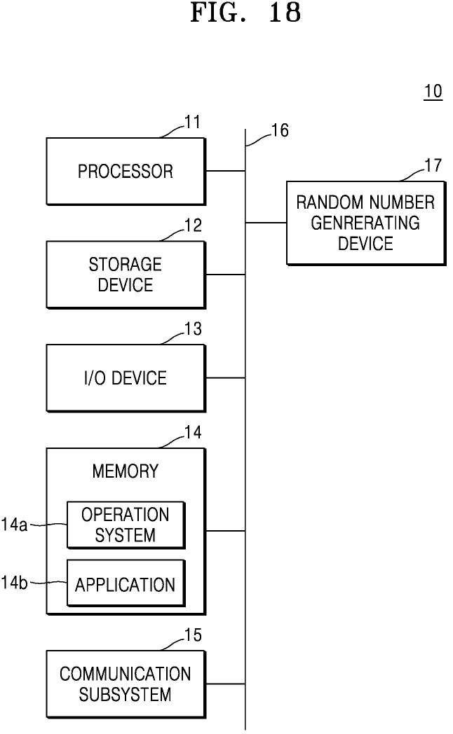

FIG. 18 is a block diagram of an apparatus 10 including a random number generating circuit according to an embodiment.

Referring to FIG. 18, the apparatus 10 may include a processor 11, a storage device 12, an input/output (I/O) device 13, a memory 14, a communication subsystem 15, a bus 16, and a random number generating device 17. The apparatus 10 may include hardware elements that may be electrically coupled to each other (or capable of communicating with each other) via the bus 16. That is, the processor 11 may include hardware elements, and the hardware elements may include one or more general-purpose processors and/or one or more special purpose processors (e.g., digital signal processing chips, graphics acceleration processors, etc.). The input/output device 13 may input/output data to be processed or to be processed by the processor 11.

The storage device 12 may include, without limitation, local and/or network accessible storage. For example, the storage device 12 may include a disk drive, a drive array, an optical storage device, a solid-state storage device, and the like. The storage device 12 may be programmable or flash-updatable, and may be implemented to be applicable to various file systems, database structures, and the like.

The communication subsystem 15 may include, without limitation, a modem, a network card (wireless or wired), an infrared communication device, a wireless communication device, and/or a chipset (e.g., Bluetooth devices, 802.11 devices, Wi-Fi devices, WiMax devices, cellular communication devices, etc.). The communication subsystem 15 may allow digital signature related data generated according to an embodiment to be exchanged with (or transmitted to) a network, other computer systems/devices, and/or any other devices.

The memory 14 includes an operation system 14a and may include an application 14b with device drivers, executable libraries, and/or program codes. The operation system 14a and the application 14b are software elements and may be implemented by executing code and/or commands by a computer (or a processor in the computer).

The random number generating device 17 according to an embodiment is a device that performs various arithmetic operations to generate an electronic signature for electronic data (or data to be signed) for security, and may generate an electronic signature for electronic data based on a certain electronic signature algorithm method. The random number generating device 17 may include a ring oscillator to generate a random number.

The ring oscillator may include a plurality of inverters in a chain form and the plurality of inverters may provide a delay corresponding to the number of the plurality of inverters. The ring oscillator may generate a pulse having an input inverted and output through the plurality of inverters and having a certain period. An inverter included in the ring oscillator may be a skew inverter configured to have different ratios of sizes of PMOS and NMOS. Ring oscillator-based random number generation technology may generate random numbers by sampling an oscillation signal that is an output of a ring oscillator by using the ring oscillator as a random source. The key to ring oscillator-based random number generation technology is that the output of the ring oscillator is affected by noise and a clock value changes faster or slower than the period, resulting in irregular output, and the quality of random numbers may vary depending on the degree and frequency of jitter.

According to an embodiment, the random number generating device 17 may sample an oscillation signal output by a ring oscillator a plurality of times and generate a random number based on logic levels of a plurality of sampled signals. For example, the random number generating device 17 may determine a logic level of the random number according to a time point at which a logic level of a sampling signal first transitions.

In an embodiment, the random number generating device 17 may be implemented as hardware logic or may include a logic block designed by logic synthesis. In addition, the random number generating device 17 may include a software block implemented by executing a set of codes and/or commands stored on a non-transitory computer-readable storage medium such as the storage device 12 by the random number generating device 17. In other embodiments, the storage medium may be provided as a device separate from a computer device (e.g., removable media such as compact disks, universal serial bus (USB), etc.) or as an installation package so that a general-purpose computer having a set of codes and/or commands stored thereon can be used for programming or adapting. These sets of code and/or commands may take the form of code executable by the random number generating device 17, and may take the form of source code and/or installable code upon compilation and/or installation on the random number generating device 17.

Various changes in form and details may be made therein without departing from the spirit and scope of the following claims.

1. A random number generating circuit comprising:
an oscillation circuit comprising a plurality of first delay elements connected to each other in series to generate an oscillation signal;
a sampling circuit comprising a plurality of second delay elements connected to each other in series to generate a plurality of sampling signals by sampling the oscillation signal at a plurality of sampling points in time based on the plurality of second delay elements; and
a random number determining circuit configured to generate a random number based on a target sampling point in time associated with a target sampling signal in which a first logic level transition occurs from among the plurality of sampling signals, wherein the plurality of sampling points comprises the target sampling point.

2. The random number generating circuit of claim 1, wherein the sampling circuit comprises a delay element chain configured to receive a clock signal, and generate a plurality of delay signals that are delayed by different delay times with respect to the clock signal.

3. The random number generating circuit of claim 2, wherein an interval between two sampling points of the plurality of sampling points is less than a period of the oscillation signal.

4. The random number generating circuit of claim 2, wherein the sampling circuit comprises a flip-flop circuit comprising a plurality of flip-flops connected to each other in parallel, each flip-flop of the plurality of flip-flops being configured to:
receive the oscillation signal and one of the plurality of delay signals, and
generate a sampling signal of the oscillation signal at a clock edge time point of the one of the plurality of delay signals.

5. The random number generating circuit of claim 4, wherein the delay element chain comprises a plurality of inverters connected in series to each other, the delay element chain being configured to:
generate the plurality of delay signals as the clock signal propagates through the plurality of inverters, and
provide a corresponding delay signal of the plurality of delay signals to a corresponding flip-flop of the plurality of flip-flops.

6. The random number generating circuit of claim 5, wherein the flip-flop circuit comprises:
a first flip-flop circuit configured to generate the sampling signal by receiving a first delay signal having a phase corresponding to the clock signal; and
a second flip-flop circuit configured to generate the sampling signal by receiving a second delay signal having an inverted phase with respect to the clock signal.

7. The random number generating circuit of claim 4, wherein the delay element chain comprises a plurality of inverters arranged as a plurality of inverter groups, the delay element chain being configured to:
generate the plurality of delay signals having the same phase from each inverter group of the plurality of inverter groups, each inverter group including two inverters from among the plurality of inverters, and
provide a corresponding delay signal of the plurality of delay signals to a corresponding flip-flop of the plurality of flip-flops.

8. The random number generating circuit of claim 1, wherein the random number determining circuit is configured to:
generate a first random number of a first logic level when an order of the target sampling signal from among the plurality of sampling signals is an odd number, and
generate a second random number of a second logic level distinct from the first logic level when the order of the target sampling signal is an even number.

9. The random number generating circuit of claim 8, wherein the random number determining circuit comprises:
a plurality of comparators configured to compare logic levels of sampling signals corresponding to sampling points adjacent in time to each other from among the plurality of sampling signals; and
a determination circuit configured to determine the order of the target sampling signal based on a result of the comparing by the plurality of comparators.

10. The random number generating circuit of claim 1, wherein the random number determining circuit is configured to generate the random number as a code mapped in response to an order of the target sampling signal from among the plurality of sampling signals.

11. (canceled)

12. A random number generator comprising:
a first delay element chain comprising a plurality of first delay elements connected to each other in series to generate an oscillation signal;
a second inverter chain comprising a plurality of second inverters connected to each other in series to generate a plurality of delay signals delayed by different delay times from a clock signal;
a sampling chain configured to generate a plurality of sampling signals of the oscillation signal based on the plurality of delay signals; and
a random number output circuit configured to:
determine a sampling signal having a logic level that is different from a logic level of a previous sampling signal, from among the plurality of sampling signals, as a target sampling signal, and
generate a random number based on a sampling order of the target sampling signal from among the plurality of sampling signals.

13. (canceled)

14. The random number generator of claim 12, wherein the random number output circuit is configured to determine the sampling signal as the target sampling signal in which a first-in-time logic level transition occurs from among the plurality of sampling signals, and the plurality of sampling signals correspond to a plurality of sampling points.

15. The random number generator of claim 14, wherein the random number output circuit is configured to:
generate a first random number of a first logic level when an order of the target sampling signal from among the plurality of sampling signals is an odd number, and
generate a second random number of a second logic level when the order of the target sampling signal is an even number.

16. The random number generator of claim 15, wherein the random number output circuit comprises:
a plurality of comparators each configured to:
compare logic levels of two sampling signals corresponding to sampling points adjacent in time to each other from among the plurality of sampling signals, and
output a result of the comparing performed by the plurality of comparators; and
a determination circuit configured to determine the order of the target sampling signal based on the result of the comparing.

17. The random number generator of claim 16, wherein each of the plurality of comparators is configured to compare one of odd-sampled signals associated with an odd sampling order with one of even-sampled signals associated with an even sampling order, from among the plurality of sampling signals.

18. The random number generator of claim 17, wherein the plurality of comparators comprises:
a first comparator configured to compare a first one of the odd-sampled signals with a first one of the even-sampled signals in a first sampling order associated with the odd sampling order; and
a second comparator configured to compare the first one of the even-sampled signals with a second one of the odd-sampled signals in a second sampling order associated with the even sampling order.

19. The random number generator of claim 12, wherein the random number output circuit generates as the random number a code mapped in response to an order of the sampling signal corresponding to a target sampling point in time at which a first-in-time logic level transition occurs.

20. A method of operating a random number generating circuit for generating a random number based on a plurality of sampling signals, the method comprising:
generating an oscillation signal by a ring oscillator;
generating the plurality of sampling signals by sampling the oscillation signal at different sampling points in time;
determining a sampling point associated with a target sampling signal in which a first logic level transition occurs, from among the plurality of sampling signals; and
generating the random number based on the sampling point of the target sampling signal.

21. (canceled)

22. (canceled)

23. (canceled)

24. (canceled)

25. The method of claim 20, wherein the generating the random number comprises:
generating a first random number of a first logic level when an order of the target sampling signal from among the plurality of sampling signals is an odd number, and
generating a second random number of a second logic level when the order is an even number.

26. The method of claim 20, wherein the generating the random number comprises:
generating, as the random number, a code mapped in response to an order of the target sampling signal from among the plurality of sampling signals.
